(19) United States
(12) Patent Application Publication
(10) Pub. No.: US 2011/0018621 A1
(43) Pub. Date: Jan. 27, 2011

(54) CURRENT MIRROR CIRCUIT

(75) Inventor: Stefan Butzmann, Beilstein (DE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/161,712

(22) PCT Filed: Jan. 25, 2007
(86) PCT No.: PCT/IB2007/050258

§ 371 Date: Oct. 14, 2010

(30) Foreign Application Priority Data
Jan. 31, 2006 (EP) 06101103.7

(51) Int. Cl. G05F 3/26; H03K 17/08

(52) U.S. Cl. 327/543

(57) ABSTRACT

The invention relates to a current mirror circuit (40, 50, 60) comprising an input-side transistor (Q₁) or field effect transistor and an output-side transistor (Q₂) or field effect transistor, which are coupled with their emitters or sources and are connected to a voltage (U_{B}, 55), which are electrically coupled with each other with their respective base (45, 46, 57, 58) or gate and are connected to a the field effect transistor (Q₃) in such a way that the source (44) of the field effect transistor (Q₃) is coupled to the base (45,46,57,58) or gate of the two transistors (Q₁, Q₂) or field effect transistors and the drain (47) of the field effect transistor (Q₃) is coupled to the collector (48) or drain of the input-side transistor (Q₁) or field effect transistor.

### FIELD OF THE INVENTION

The invention relates to a current mirror circuit comprising an input-side transistor and an output-side transistor, which are coupled with their emitters or sources and are connected to a voltage. The transistors may be bipolar transistors or field effect transistors.

### BACKGROUND OF THE INVENTION

Current mirror circuits as such are known from the state of the art. A current mirror is, for example, a current-controlled power source, that is, an amplified, reduced or identical copy of the input-side current is obtained at the input.

Current mirror circuits with a sensor are also operated as a source of input current. This offers the advantage that the voltage does not change much at ambient temperature via the sensor, if the input current doubles. This means that the supply voltage variation via the sensor is small compared to the fact that a measuring resistor connected in series with the sensor is used. Such a known current mirror is represented in FIG. 1 as state of the art.

However, such current mirrors have the disadvantage that in the case of a short-circuit to ground the transistors of the current mirror may be destroyed, because the base-emitter voltage is increased to the supply voltage level. In the case of a low-impedance connection to ground, a very high current then flows through both transistors, so that there is a great danger of thermal destruction of the transistors due to the dissipated power.

In order to prevent this and to protect the current mirror circuit, protective circuits are used, which determine and limit the current by means of a voltage drop through an additional resistor. Such circuits according to the state of the art are represented in FIGS. 2 and 3. However, these have the disadvantage of a large voltage drop between the collector of a first transistor and the supply or battery voltage, which has the direct effect of the sensor supply voltage being reduced, which is, however, not desired.

Abstract of JP 05-303 439 discloses a current mirror circuit comprising two safety resistors connected to ground and an input-side safety resistor, which is switched between the collector and the base of a third transistor.

EP 0602699 A2 discloses a current limiting circuit comprising a measuring transistor and a measuring resistor.

### OBJECT AND SUMMARY OF THE INVENTION

It is an object of the invention to provide a current mirror circuit, which has a protection against the danger of destruction in the case of a short-circuit to ground and yet does not have a large voltage drop between the collector and the battery or supply voltage.

The object is achieved according to the invention with the characteristics of claim 1, with a current mirror circuit having an input-side transistor or field effect transistor and an output-side transistor or field effect transistor, which are coupled with their emitters or sources and are connected to a voltage, which are electrically coupled with each other and are connected to a further field effect transistor in such a way that the source of the further field effect transistor is coupled to the base or the gate of the two transistors or field effect transistors and the drain of the further field effect transistor is coupled to the collector or the drain of the input-side transistor or field effect transistor.

The fact of being coupled may be achieved hereinafter both by means of direct coupling or by means of indirect coupling, so that for example, a coupling via a coupling capacitor or another circuit element is also understood to mean a coupling.

Here, it is advantageous if the emitters of the input-side transistor and the output-side transistor are connected to supply voltage U_{B}.

Furthermore, it is also expedient, if the field effect transistor is a p-channel field effect transistor such as advantageously a MOSFET.

Furthermore, it is advantageous, if the input-side transistor and the output-side transistor are pnp transistors.

With a further advantageous example of embodiment, a sensor is coupled with one connection to the collector of the input-side transistor and is coupled to ground with the other connection. Such a sensor may be for example, a sensor of an ABS system of a motor vehicle.

With a further example of embodiment, the emitters of the input-side transistor and the output-side transistor are connected to ground.

It is particularly expedient if the field effect transistor is an n-channel field effect transistor, such as particularly a MOSFET. It is also expedient, if the input-side transistor and the output-side transistor are npn transistors and a sensor is coupled with one connection to the collector of the input-side transistor and is connected with the other connection preferably to supply voltage U_{B}.

It is particularly advantageous if the gate of the field effect transistor is coupled to a control circuit.

Here, an embodiment is advantageous in which the control circuit has a transistor which is coupled with its collector to the gate of the field effect transistor, with its base at least to the base of the input-side transistor of the current mirror and with its emitter at least to the emitter of the input-side transistor.

The advantageous embodiments according to the invention described above, are represented with bipolar transistors, whereas instead of the bipolar transistors field effect transistors, such as MOSFETs may also be used, while instead of the emitter of the bipolar transistor the source of the field effect transistor, and instead of the collector of the bipolar transistor the drain of the field effect transistor, and instead of the base of the bipolar transistor the gate of the field effect transistor is to be connected. The pnp transistor is then advantageously a p-channel field effect transistor and an npn transistor is then advantageously an n-channel field effect transistor, such as a MOSFET.

Advantageous further embodiments are described in the dependent claims.

### BRIEF DESCRIPTION OF THE DRAWINGS

These and other aspects of the invention are apparent from and will be elucidated with reference to the embodiments described hereinafter.

In the drawings:

FIG. 1 gives a schematic representation of a current mirror circuit according to the state of the art;

FIG. 2 gives a schematic representation of a current mirror circuit according to the state of the art;

FIG. 3 gives a schematic representation of a current mirror circuit according to the state of the art;

FIG. 4 gives a schematic representation of a current mirror circuit according to the invention;

FIG. 5 gives a schematic representation of a current mirror circuit according to the invention;

FIG. 6 gives a schematic representation of a current mirror circuit according to the invention;

FIG. 7 gives a schematic representation of a current mirror circuit according to the invention;

FIG. 8 gives a schematic representation of a current mirror circuit according to the invention;

FIG. 9 gives a schematic representation of a current mirror circuit according to the invention; and

FIG. 10 gives a schematic representation of a current mirror circuit according to the invention.

### DESCRIPTION OF EMBODIMENTS

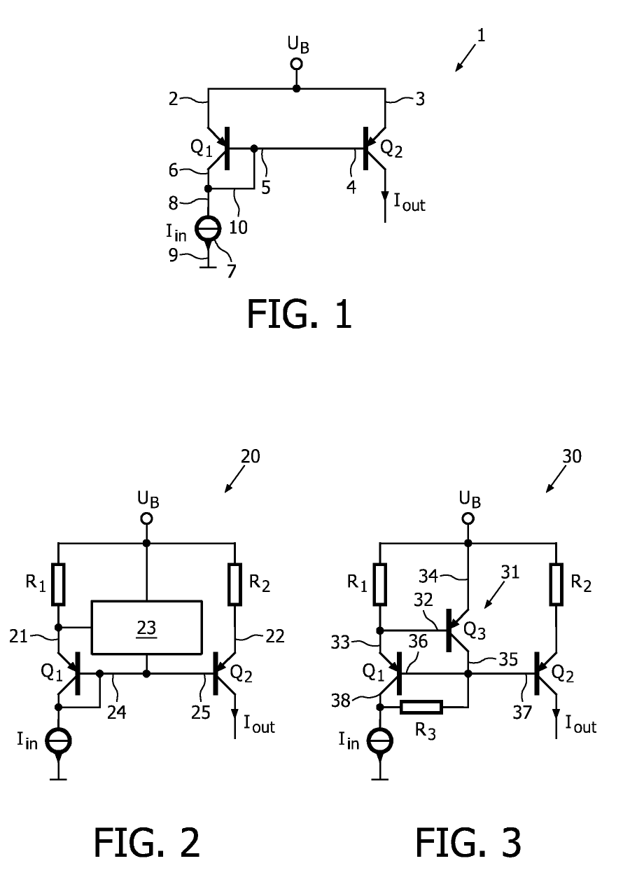

FIG. 1 shows a current mirror circuit 1 in which two transistors, an input-side transistor Q₁ and an output-side transistor Q₂ are connected with the respective emitter 2, 3 to supply voltage U_{B}. The bases 4,5 of the transistors Q₁, Q₂ are coupled to each other. A sensor 7 is connected to the collector 6 of the transistor Q₁, which sensor preferably has a two-wire interface, wherein a connection 8 such as a wire is coupled to the collector 6 and the other connection 9 is coupled to ground. Furthermore, there is a connection 10 between the base 5 of the transistor Q₁ and the collector 6 of Q₁. With the current mirror circuit 1, the power source Iᵢₙ is formed as a sensor 7 with a two-wire interface. This has the advantage already described above that the voltage changes only little via the sensor if the input current Iᵢₙ is doubled at ambient temperature. This also means that the voltage variation is small compared to an arrangement of a measuring resistor in series with the sensor 7. However, a disadvantage in this circuit is the danger of the destruction of the transistors Q₁ and/or Q₂ in the case of a short-circuit to ground. In this case, the base emitter voltage would increase to the supply voltage level and the transistors could be destroyed. But in the case of only a low-impedance connection to ground also a large current would flow through the two transistors, so that these could be thermally destroyed due to the dissipated power.

For this reason current mirror circuits are provided with protective measures, as represented in FIG. 2. In FIG. 2 a current mirror circuit 20 is shown, in which two resistors R₁ and R₂ are provided in the circuit according to FIG. 1, while R₁ is switched between U_{B} and the emitter 21 of Q₁ and R₂ is switched between emitter 22 of Q₂ and U_{B}. Furthermore, a protective circuit 23 is provided between the respective base 24,25 of Q₁ and Q₂, the emitter 21 of Q₁ and U_{B}. Otherwise, the circuit 20 corresponds to the circuit 1 of FIG. 1 and is therefore not described any further. The circuit of FIG. 2 makes use of an additional measuring resistor R₁ for measuring and limiting the input current via the voltage drop.

FIG. 3 shows a respective appropriate current mirror circuit 30 in which a pnp transistor Q₃,31 is included instead of the protective circuit 23 of FIG. 2. The former is coupled with its base 32 to the emitter 33 of transistor Q₁, with its emitter 34 to U_{B} and with its collector 35 to the base 36,37 of Q₁ and Q₂. Furthermore, an additional resistor R₃ is switched between the collector 38 of Q₁ and the base 36 of Q₁. This circuit 30 causes the input current Iᵢₙ to be limited to a value of 0.6 V/R₁, so that, consequently, a protection of the current mirror is achieved. However, this protection is obtained by a significant voltage drop between the collector of Q₁ and U_{B}, which causes a disadvantageous reduction in the sensor supply voltage.

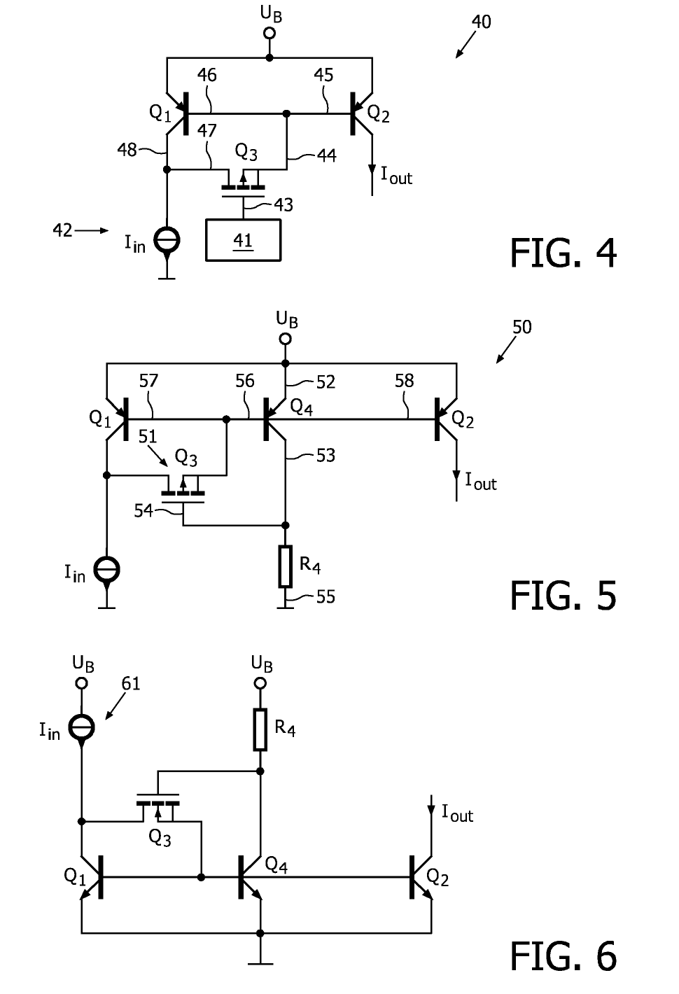

In contrast to this, the advantageous current mirror circuit 40 according to the invention is schematically represented in FIG. 4. The circuit according to FIG. 4 corresponds to the circuit of FIG. 1, wherein additionally a p-channel field effect transistor Q₃ is provided in the collector base connection of Q₁ and a control circuit 41 is provided for the field effect transistor Q₃. Here, the field effect transistor Q₃ is connected in such a way that the gate 43 is coupled to the control circuit 41 and the source 44 is coupled to the base 45,46 of the two transistors Q₁, Q₂ and the drain 47 is coupled to the collector 48 of Q₁.

If the transistor Q₃ is operated in the linear mode, it produces a low-impedance connection between the drain and source and an appropriate direct connection between them. The current mirror 40 then functions like the current mirror in FIG. 1. If, however the current flow through transistor Q₁ becomes too large, the gate potential increases, so that Q₃ goes into the saturation mode, so that the current flow from the collector of the transistor Q₁ is reduced. A possible short circuit at the input 42 of the current mirror then results in a defined maximum current flow in and out of the current mirror, that is, Iᵢₙ and Iₒᵤₜ are limited. Thus, the circuit 40 is effectively protected for example, against short circuit to ground and its consequences.

FIG. 5 shows a simple circuit 50 for controlling the field effect transistor Q₃, 51, which essentially corresponds to the field effect transistor Q₃ of FIG. 4. In FIG. 5 a transistor Q₄ is provided for control, which is connected on the emitter side 52 to the battery or supply voltage U_{B} and on the collector side to the gate 54 of the field effect transistor Q₃ and is connected to ground 55 through a resistor R₄. The base 56 of Q₄ is coupled to the respective base 57,58 of Q₁ and Q₂. If only a small current Iᵢₙ flows into the transistor Q₁, the voltage drop is R₄*IC₄, wherein IC₄ is the collector current of Q₄, and the gate source voltage of Q₃ is high. In this case, Q₃ is turned on and functions like a short-circuit or like a low-impedance resistor.

However, if the input current increases, the gate source voltage of Q₃ will decrease and if a cut-off voltage is reached, then Q₃ will change to the turned-off state and thus limit the input current Iᵢₙ of the current mirror 50.

According to the invention, it is further advantageously possible, if the resistor R₄ is used for the evaluation of a connected micro-controller. This may preferably take place in the normal operating state as long as the maximum voltage keeps the field effect transistor Q₃ turned on. In this case, the transistor Q₂ could even be omitted.

FIG. 6 shows a further example of embodiment of a current mirror 60 according to the invention, wherein the current mirror is arranged on the ground-side of the sensor 61. This means that the transistors Q₁, Q₂ and Q₄ are designed as npn transistors in comparison with the pnp transistors of FIG. 5 and the field effect transistor Q₃ is designed as an n-channel field effect transistor, such as for example, an n-channel-MOSFET. Thus, the circuit vis-à-vis the circuit of FIG. 5 is inverted in such a way that the sensor input of sensor 61 and the resistor R₄ are connected to U_{B} and the emitters of Q₁, Q₂ and Q₄ are connected to ground.

The examples of embodiment of current mirror circuits according to the invention described in FIGS. 4 to 6 may be represented with field effect transistors also instead of bipolar transistors. In order to avoid repetitions here, instead of the emitter of the bipolar transistor the source of the field effect transistor is to be connected and instead of the collector of the bipolar transistor the drain of the field effect transistor is to be connected and instead of the base of the bipolar transistor the gate of the field effect transistor is to be connected. The pnp transistor is then advantageously a p-channel field effect transistor and an npn transistor is then advantageously an n-channel field effect transistor, such as a MOSFET.

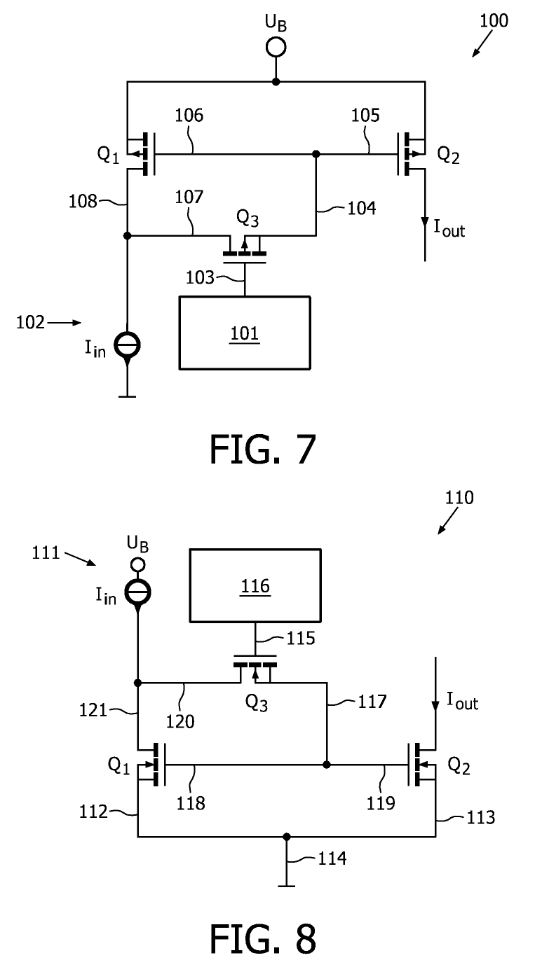

Such current mirror circuits, according to the invention are represented in FIGS. 7 to 10. FIG. 7 shows a current mirror circuit 100 according to the invention analogous to the current mirror circuit 40 of FIG. 4. The circuit 100 according to FIG. 7 corresponds to the circuit of FIG. 4, wherein a p-channel field effect transistor Q₃ is additionally provided in the drain-gate connection of the field effect transistor Q₁ and a control circuit 101 for the field effect transistor Q₃. Here, the field effect transistor Q₃ is then connected in such a way that the gate 103 is coupled to the control circuit 101 and the source 104 is coupled to the gate 105,106 of the two field effect transistors Q₁, Q₂ and the drain 107 is coupled to the drain 108 of Q₁.

If the transistor Q₃ is operated in the linear mode, it again produces a low-impedance connection between drain and source and an appropriate direct connection between them. The current mirror 100 then functions like the current mirror in FIG. 1. However, if the current flow through transistor Q₁ becomes too large, the gate potential increases, so that Q₃ goes into the saturation mode, so that the current flow from the drain of the transistor Q₁ is reduced. A possible short-circuit at the input 102 of the current mirror then results in a defined maximum current flow in and out of the current mirror, which means that Iᵢₙ and Iₒᵤₜ are limited. Thus, the circuit 100 is effectively protected for example, against short-circuit to ground and its consequences.

FIG. 8 shows a current mirror circuit 110, with which the input 111 is connected to supply potential U_{B} and the source 112, 113 of the field effect transistor Q₁ and Q₂ is connected to ground potential. Otherwise, the circuits 100 and 110 correspond except for the use of n-channel field effect transistors in circuit 110 and p-channel field effect transistors in circuit 100. Here, the field effect transistor Q₃ is connected in such a way that the gate 115 is coupled to the control circuit 116 and the source 117 is coupled to the gate 118,119 of the two field effect transistors Q₁, Q₂ and the drain 120 is coupled to the drain 121 of Q₁.

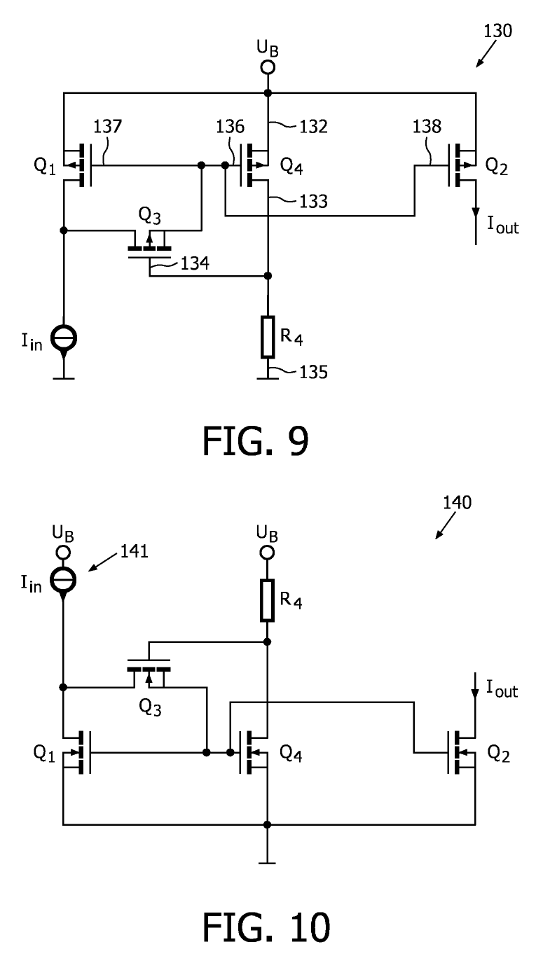

FIG. 10 shows a simple current mirror circuit 130 for controlling the field effect transistor Q₃, which in essence corresponds to the field effect transistor Q₃ of FIG. 7. In FIG. 9 a further field effect transistor Q₄ is provided for control purposes, which is connected on the source-side 132 to the battery or supply voltage U_{B} and on the drain side 133 to the gate 134 of the field effect transistor Q₃ and is connected to ground through a resistor R₄. The gate 136 of Q₄ is coupled to the respective gate 137,138 of Q₁ and Q₂.

FIG. 10 shows a further example of embodiment of a current mirror 140 according to the invention, wherein the current mirror is arranged on the ground side of the sensor 141. This means that the field effect transistors Q₁, Q₂, Q₃ and Q₄ are designed as n-channel field effect transistors, such as for example n-channel-MOSFETs. Thus, the circuit is inverted vis-à-vis the circuit of FIG. 9 in such a way that the sensor input of sensor 141 and the resistor R₄ are connected to U_{B} and the sources of Q₁, Q₂ and Q₄ are connected to ground potential.

1. A current mirror circuit (40, 50, 60) comprising an input-side transistor (Q₁) or field effect transistor and an output-side transistor (Q₂) or field effect transistor, which are coupled with their emitters or sources and are connected to a voltage (U_{B}, 55), which with their respective base (45,46,57,58) or gate are electrically coupled with each other and connected to a field effect transistor (Q₃) in such a way that the source (44) of the field effect transistor (Q₃) is coupled to the base (45,46,57,58) or the gate of the two transistors (Q₁, Q₂) or field effect transistors and the drain (47) of the field effect transistor (Q₃) is coupled to the collector (48) or the drain of the input-side transistor (Q₁) or field effect transistor.

2. A current mirror circuit as claimed in claim 1, characterized in that the emitter or source of the input-side transistor (Q₁) or field effect transistor and of the output-side transistor (Q₂) or field effect transistor are connected to supply voltage U_{B}.

3. A current mirror circuit as claimed in claim 1 or 2, characterized in that the field effect transistor (Q₃) is a p-channel field effect transistor.

4. A current mirror circuit as claimed in 1, 2 or 3, characterized in that the input-side transistor (Q₁) and the output-side transistor (Q₂) is a respective pnp-transistor or input-side field effect transistor and the output-side field effect transistor is a respective p-channel-field effect transistor, such as a MOSFET.

5. A current mirror circuit as claimed in any one of the preceding claims, characterized in that a sensor (61) is coupled with one connection to the collector (48) or the drain of the input-side transistor (Q₁) or field effect transistor and is coupled to ground (55) with the other connection.

6. A current mirror circuit as claimed in claim 1, characterized in that the emitter or source of the input-side transistor (Q₁) or field effect transistor and that of the output-side transistor (Q₂) or field effect transistor are connected to ground (55).

7. A current mirror circuit as claimed in claim 1 or 6, characterized in that the field effect transistor (Q₃) is an n-channel field effect transistor, such as a MOSFET.

8. A current mirror circuit as claimed in 1, 6 or 7, characterized in that the input-side transistor (Q₁) and the output-side transistor (Q₂) is a respective npn transistor or n-channel field effect transistor, such as a MOSFET.

9. A current mirror circuit as claimed in any one of the preceding claims, characterized in that a sensor (61) is coupled with one connection to the collector or drain of the input-side transistor (Q₁) or field effect transistor and is connected to the supply voltage U_{B} with the other connection.

10. A current mirror circuit as claimed in any one of the preceding claims, characterized in that the gate (43,54) of the field effect transistor (Q₃) is coupled to a control circuit (41).

11. A current mirror circuit as claimed in claim 10, characterized in that the control circuit (41) comprises a transistor (Q₄) or field effect transistor which is coupled with its collector (53) or drain to the gate (54) of the field effect transistor (Q₃), with its base (56) or gate to at least the base (57) or gate of the input-side transistor (Q₁) or field effect transistor of the current mirror and is coupled with its emitter (52) or source to at least the emitter or source of the input-side transistor (Q₁) or field effect transistor.
